(19) United States
(12) Patent Application Publication
(10) Pub. No.: US 2012/0273347 A1
(43) Pub. Date: Nov. 1, 2012

(54) SPUTTERING TARGET WITH REDUCED PARTICLE GENERATION AND METHOD OF PRODUCING SAID TARGET

(75) Inventor: Kei Koide, Ibaraki (JP)

(73) Assignee: JX NIPPON MINING & METALS CORPORATION, Tokyo (JP)

(21) Appl. No.: 13/518,484

(22) PCT Filed: Dec. 6, 2010
(86) PCT No.: PCT/JP2010/071786

§ 371 Date: Jul. 17, 2012

(30) Foreign Application Priority Data
Dec. 25, 2009 (JP) 2009-295475

(51) Int. Cl. C23C 14/34; B24B 1/00

(52) U.S. Cl. 204/298.12; 451/41

(57) ABSTRACT

Provided is a sputtering target with reduced particle generation having a target surface in which intermetallic compounds, oxides, carbides, carbonitrides and other substances without ductility exist in a highly ductile matrix phase at a volume ratio of 1 to 50%, and in which the area ratio of defects on the target surface is 0.5% or less, as well as a method of producing such a sputtering target. Additionally provided are a sputtering target wherein the target surface, which contains large amounts of substances without ductility, is improved, and whereby the generation of nodules and particles during sputtering can be prevented or inhibited, and a surface finishing method thereof.

### BACKGROUND OF THE INVENTION

The present invention relates to a sputtering target with reduced particle generation and minimal surface defects in which intermetallic compounds, oxides, carbides, carbonitrides and other substances without ductility exist in a highly ductile matrix phase, and to the surface finishing method thereof.

The sputtering method is a well-known technique as a means for forming a thin film. The basic principle thereof is to apply, in a lean gas of argon or the like, a voltage between a substrate (anode side) to which the thin film is formed and a target (cathode side) facing the substrate at a close distance and which is formed from a thin film forming substance, so as to change argon gas into a plasma. The consequently generated argon ions collide with the target, which is a cathode material, the energy thereof discharges (sputters) the target material outside, and the discharged material is laminated on the opposed substrate face.

A thin film forming device employing this sputtering principle includes various modified types such as a bipolar bias sputtering device, a radio frequency sputtering device, a plasma sputtering device and so on, but all of these devices employ the same basic principle.

The material for forming the thin film is referred to as a target, since it becomes the target of the argon ions. Since this target is formed from the collision energy of ions, the thin film forming material constituting the target is laminated on the substrate in an atomic form, or a cluster form formed from an aggregate of such atoms. As a result, a fine and accurate thin film can be formed, and this is the reason it is being widely used in various electronic components today.

Recently, this sputtering used for forming thin films is being demanded of extremely sophisticated deposition methods, and an important task is to form films with few defects.

The generation of such defects in this sputtering process is not only attributable to the sputtering method, but also frequently to the target itself. As such a cause of the generation of defects resulting from the target, there is the generation of particles and nodules.

Under normal conditions, the material sputtered (discharged) from the target will adhere to the opposed substrate, but the material is not necessarily sputtered perpendicularly, and is discharged in various directions. This kind of discharged material will adhere to the components inside the sputtering device other than the substrate, and this at some point will peel off, float, and reattach to the substrate, or generate arcing on the target surface (particles of 1 μ or less adhere to the substrate due to an abnormal discharge).

This kind of material is referred to as particles, and these particles will cause a short circuit in the fine wiring film of electronic components, for example, and lead to the generation of defective products. It is known that the generation of particles is caused by the discharge of the material from the target, and will increase or decrease depending on the surface condition of the target.

Furthermore, generally, the target face material does not decrease (erode) uniformly in the sputtering process, but the tendency is for a specific area, a ring shape for example, to be eroded depending on the inherent characteristics of the constituent material and sputtering device, method of applying voltage, among other factors. Moreover, a protrusive substance with numerous bumps known as nodules is sometimes formed on the target depending on the type of target material or the manufacturing method of the target.

The substance is one of the thin film forming materials and will not directly affect a thin film. However, minute arcs (microarcing) are generated at the protrusions of the nodules, and it has been observed that this results in the increase of particles.

Generation of numerous nodules will change the sputtering rate to delay and make the control of the deposition difficult. At times, these rough and large nodules will peel off and adhere to the substrate.

In such a case, the nodules themselves will become a significant obstacle. Thus, it is sometimes necessary to temporarily stop the sputtering process to remove the nodules. This results in a problem of deteriorating the operation efficiency.

Recently, a target is not formed from a uniform material but is often used in a state where intermetallic compounds, oxides, carbides, carbonitrides and other substances are mixed in a ductile matrix phase. Here, there is a problem in that the generation of nodules and particles will increase.

As conventional technology, proposed is a sputtering target in which the processing defect layer (fracture layer) containing minute cracks and defective parts arising during the machine work is removed from the surface of a high-melting point metal alloy sputtering target (refer to Patent Document 1). Disclosed is another technique for uniformizing the film and inhibiting the generation of nodules and particles by adjusting the surface roughness of the sputtering target so as to reduce the amount of residual contamination, hydrogen content on the surface, and thickness of the affected layer (refer to Patent Document 2).

There are other proposals: a proposal of making the surface roughness Ra 0.01 μm or less via mechanochemical polishing to inhibit the generation of particles (refer to Patent Document 3), and a proposal of making the half-value width of the peak of the crystal plane (110) 0.35 or less to inhibit the generation of particles on sputtering a tungsten target (refer to Patent Document 4). Although these technologies anticipate that the generation of nodules and particles will considerably affect the surface condition of the target, in reality they have not resolved the problems.

Also proposed is a sputtering target having a target surface in which intermetallic compounds, oxides, carbides, carbonitrides and other substances without ductility exist in a highly ductile matrix phase at a volume ratio of 1 to 50%, wherein defects of 10 μm or larger caused by machining do not exist (refer to Patent Document 5). This was proposed by the present applicant, and is an effective means among the known documents. However, there was room for improvement for the further prevention of the generation of nodules and particles. The present invention is an improvement of Patent Document 5.

[Patent Document 1] Japanese Unexamined Patent Application Publication No.H3-257158

[Patent Document 2] Japanese Unexamined Patent Application Publication No.H11-1766

[Patent Document 3] Japanese Unexamined Patent Application Publication No.H10-158828

[Patent Document 4] Japanese Unexamined Patent Application Publication No 2003-49264

[Patent Document 5] International Publication No.WO2005-083148

### SUMMARY OF THE INVENTION

### Problems to be Solved by the Invention

An object of the present invention is to provide a sputtering target with superior surface characteristics that is able to improve the target surface in which intermetallic compounds, oxides, carbides, carbonitrides and other substances without ductility exist in a highly ductile matrix phase, and prevent or inhibit the generation of nodules and particles upon sputtering, and to provide the surface finishing method thereof.

### Means for Solving the Problems

The present invention provides:
1) A sputtering target with reduced particle generation having a target surface in which intermetallic compounds, oxides, carbides, carbonitrides and other substances without ductility exist in a highly ductile matrix phase at a volume ratio of 1 to 50%, and in which the area ratio of defects on the target surface is 0.5% or less; and
2) The sputtering target with reduced particle generation according to 1) above, wherein the number of defects in a size of 0.001 to 0.04 μm² on the target surface is 90% or more relative to the total number of defects.

The present invention additionally provides:
3) A surface finishing method of a sputtering target with reduced particle generation, wherein a target surface in which intermetallic compounds, oxides, carbides, carbonitrides and other substances without ductility exist in a highly ductile matrix phase at a volume ratio of 1 to 50% is preliminarily subject to primary processing of cutting work, then subsequently subject to finish processing via polishing in order to form a surface in which the area ratio of defects on the target surface is 0.5% or less; and
4) The surface finishing method of a sputtering target according to 3) above, wherein the number of defects in a size of 0.001 to 0.04 μm² on the target surface is 90% or more relative to the total number of defects.

With the present invention, as a result of a target surface in which intermetallic compounds, oxides, carbides, carbonitrides and other substances without ductility exist in a highly ductile matrix phase at a volume ratio of 1 to 50% being preliminarily subject to the primary processing of cutting work, then subsequently subject to finish processing via polishing, a target with a smooth surface and superior surface characteristics can be obtained. As a result of sputtering this target, a significant effect is yielded in that the generation of particles and the generation of nodules after the use of the target can be significantly reduced.

### BRIEF DESCRIPTION OF THE DRAWINGS

FIG. 1 is a micrograph showing a representative example upon observing the lathed face of the target material (magnification: ×6000).

FIG. 2 is a diagram showing an image upon performing three-dimensional shape analysis, via a laser microscope, to the lathed surface of the target material shown in FIG. 1.

FIG. 3 is a micrograph showing the target surface in which the lathed face of the target material shown in FIG. 1 was further subject to grinding processing (surface polishing) (magnification: ×6000).

FIG. 4 is a diagram showing the results upon performing three-dimensional shape analysis, via a laser microscope, to the target surface that was subject to the grinding processing (surface polishing) shown in FIG. 3.

FIG. 5 is a micrograph of the target of Example 1 in which Co, Cr, Pt, and SiO₂ were used as the raw material and which was subject to the cutting and polishing of the present invention (magnification: ×6000).

FIG. 6 is a diagram showing an example of selecting an arbitrary field of vision (of five locations on the target surface) to examine the size and quantity of defects on the target surface.

### DETAILED DESCRIPTION OF THE INVENTION

The target subject to the surface finishing of the present invention is a target in which intermetallic compounds, oxides, carbides, carbonitrides and other substances without ductility are mixed in a highly ductile matrix phase at a volume ratio of 1 to 50%. A typical example of this kind of target is a magnetic material, and Co, Cr, Pt, B, Ru and the like may be used as a substance without ductility.

Moreover, as substances without ductility, there are such oxides, carbides, carbonitrides as Cr, Ta, Si, Ti, Zr, Al, Nb, B, Co. Furthermore, as the intermetallic compounds, there are the intermetallic compounds of the constituent elements.

These are representative substances, and the present invention is not limited to these materials, and it goes without saying that the present invention can also be applied to other similar materials.

When this kind of target material with substances without ductility being mixed therein is subject to cutting work with a cutting tool, for example, with the location where intermetallic compounds, oxides, carbides, carbonitrides and other substances without ductility exist as the point of origin, defects (dents) in the form of cracks, indentations caused by fall-offs (the indentations are hereinafter referred to as shedding), or occasionally the defect that cut grains remain in indentations occurs.

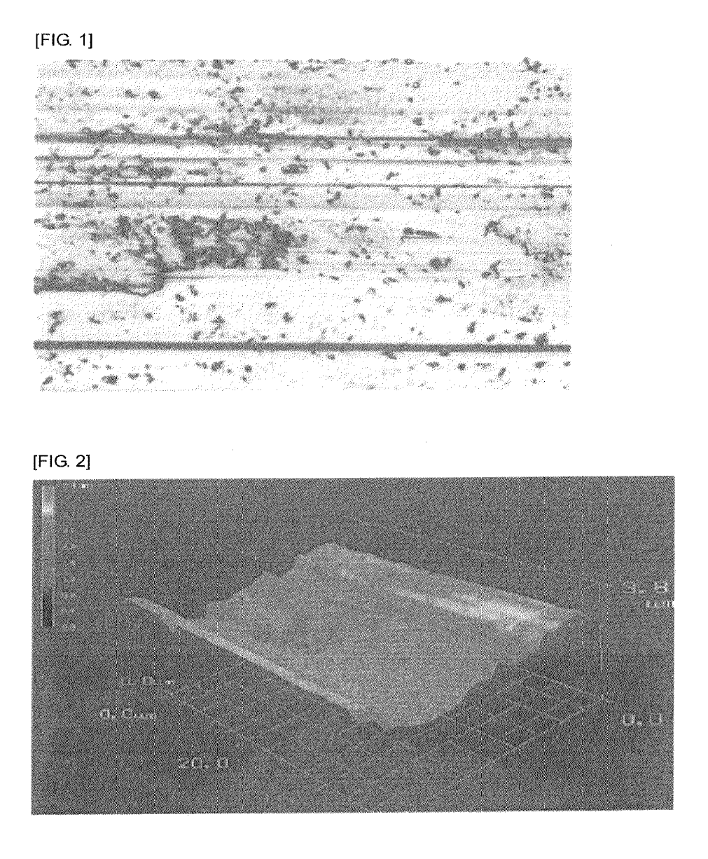

Upon observing the face of the target material that was subject to lathe processing, the lathed face as shown in FIG. 1 is formed. Here, shown is a face of a magnetic material, in which oxide (SiO₂) particles are dispersed in a cobalt-chromium-platinum alloy (CCP), that was subject to lathe processing, and numerous oxide (SiO₂) particle exist in a matrix phase on the lathed face (portions shown as black spots). Meanwhile, there are numerous streaks on the lathed face caused by the cutting tool, and the lathed face is not a smooth face. FIG. 2 shows the lathed face.

FIG. 2 shows the results of performing three-dimensional shape analysis, via a laser microscope, to the lathed face. The analytical conditions were as follows. Laser was irradiated on the target surface, the irregularities on the target surface were used as a measurement image (height data) shown with shading based on the luminance information of the quantity of light of the laser that was reflected off the surface, the inclination of the measured surface itself as a sample was represented as an approximate curve measured based on the least-square method using an X axis and a Y axis, respectively, and the surface of the shape analysis was obtained by correcting the foregoing measured surface to be flat. Note that, with the deepest point of the target surface as point 0, it is possible to display a histogram of the surface irregularities (height data) by measuring and displaying the target surface in μm units (to the thousandth place). It is thereby possible to confirm the 3σ and average value of the height data distribution (histogram).

With the surface condition of the foregoing target, it is not possible to prevent or inhibit the generation of nodules and particles. Thus, grinding processing, namely, surface polishing is performed. The conditions of such surface polishing are explained later, but what is important upon performing the surface polishing is to make the area ratio of defects on the target surface 0.5% or less.

Representative surface defects are cracks, shedding of intermetallic compounds, oxides, carbides, carbonitrides, and other substances without ductility, and occasionally the defect that cut grains remain in indentations occurs. In the present invention, grinding processing (surface polishing) is performed until the area ratio of these defects becomes 0.5% or less.

It should be easy to understand that, with the area ratio being 0.5% or less, the number of defects on the overall target surface is few. This condition is an important requirement for preventing or inhibiting the generation of nodules and particles in the target.

FIG. 3 is the micrograph of the target surface that was subject to grinding processing (surface polishing) so as to achieve the foregoing condition. In FIG. 3, no grinding marks from the cutting tool can be seen, and a condition where oxide (SiO₂) granules dispersed in a cobalt-chromium-platinum alloy (CCP) is observed.

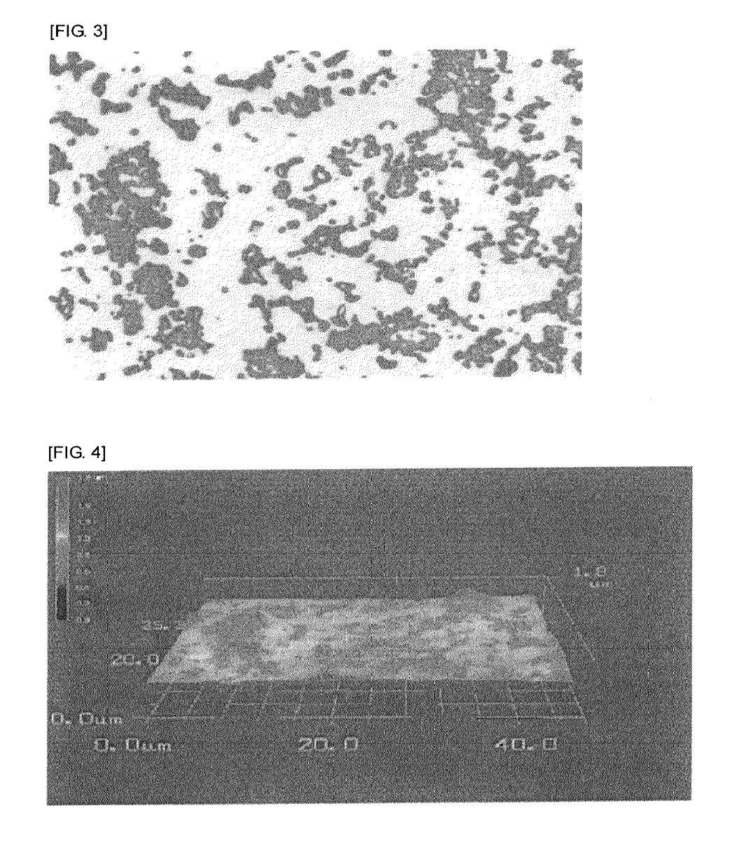

FIG. 4 shows the results upon performing three-dimensional shape analysis, via a laser microscope, to the target surface of FIG. 3 that was subject to grinding processing (surface polishing) with the same method as described above.

In the present invention, an important requirement upon evaluating a sputtering target with reduced particle generation is that, in particular, the number of defects in a size of 0.001 to 0.04 μm² on the target surface accounts for 90% or more relative to the total number of defects. This implies that, the smaller the defects, the less generation of particles, and, the smaller the defects, the smaller the abnormal charged area during sputtering and, consequently, arcing caused by abnormal discharge can be inhibited.

Thus, the good or bad of the target is evaluated based on the area ratio of defects relative to the overall target surface, and is a conclusive evaluation upon preventing or inhibiting the generation of nodules and particles. Besides, the size of the defects can also determinate the good or bad of the target.

The generation of nodules and particles is often caused by the quantity of defects, but the generation of nodules and particles of the target can be inhibited by limiting the size of these defects. It is possible to obtain an even more favorable target by causing the number of defects in a size of 0.001 to 0.04 μm² to be 90% or more relative to the total number of defects.

Note that, in the present invention, the term “defects” on the target surface is defined as follows.

On the surface that was subject to grinding processing (surface polishing), the location where arcing occurred at a stage prior to the generation of particles is referred to as the location “exceeding average value +3σ”, and this location is defined as a defect. Meanwhile, on the surface that was subject to surface grinding processing, the location where arcing occurred at a stage prior to the generation of particles is referred to as the location of “average value +3σ or more” and the location of “average value −3σ or less”, and these locations are defined as a defect. The average value and 3σ thereof can be confirmed from the three-dimensional shape analysis via a laser microscope.

In addition, the present invention can provide a sputtering target in which the elevated level caused by intermetallic compounds, oxides, carbides, carbonitrides, other substances without ductility existing in a highly ductile matrix phase is 0.05 μm or less relative to the level of the highly ductile matrix phase. The generation of nodules and particles of the target is often caused by the protrusions on the target surface.

Accordingly, the generation of nodules and particles of the target can be further reduced by reducing, as much as possible; the existence of protrusions, or bumps, on the target surface after the target surface is polished. The present invention is able to propose such a target, and covers all of the foregoing aspects.

In the present invention, after performing the primary processing of cutting an area of preferably 1 mm to 10 mm from the surface of the target material, the finishing processing via polishing is subsequently performed. The reason for cutting an area of 1 mm to 10 mm is to effectively remove the defects on the target material surface that were previously formed thereon. Cutting can be performed via lathe processing employing a cutting tool or a chip.

Note that, after performing the foregoing primary processing, it is also possible to perform grinding (surface grinding). This grinding work is not an essential process, but is effective in reducing defects (fragments and cracks) caused by cutting and process-damaged layers that do not appear on the surface, and is preferably performed as necessary since it also affects the reduction of particles.

As a result of this cutting processing as a primary processing, the generation of defects such as cracks and indentations caused by fall-offs as described above will occur, however, such defects are polished with sandpaper or a grindstone having a rough grain size of, for instance, #80 to #400. Thereby, the foregoing defects such as cracks and indentations caused by fall-offs are eliminated, and a flat and smooth target face is formed thereby.

In addition, the present invention performs grinding processing (surface polishing). This grinding processing (surface polishing) can be performed after the foregoing cutting work, or after performing grinding using sandpaper or a grindstone having a rough grain size of #80 to #400.

The grinding processing of the present invention is the SSP (Sputtering Target Surface Polishing) processing including the steps of wet primary polishing based on pure water drop→wet secondary polishing based on alumina abrasive-grain drop, and it is thereby possible to prepare a target that is flat and free from surface defects such as cracks and dents caused by fallouts.

The grinding processing of the present invention can be performed, for example, based on the following: (A) pure water (flow rate: 0.5 l/min), polishing pressure (0.3 Mpa), rotating speed of the target and pad (target: 400 rpm, pad: 130 rpm), diamond pad according to various oxides (roughness: #800), and polishing time of 10 to 20 min (to be adjusted according to the target diameter).

Moreover, the grinding processing of the present invention can also be performed, for example, based on the following: (B) alumina abrasive-grain (neutral type: PH 7±0.5), drip rate (to be adjusted arbitrarily), polishing pressure (0.3 Mpa), rotating speed of the target and pad (target: 400 rpm, pad: 130 rpm), polishing time of various oxides of 15 to 20 min (to be adjusted according to the target diameter), and neutral type polishing material. It is thereby possible to perform polishing while preventing the corrosion of the metal portion, and minimizing the difference in the grindability of the metal portion and the oxides.

What is important in the present invention is that the area ratio of defects on the target surface should be made to 0.5% or less by adjusting the foregoing grinding processing. It is thereby possible to improve the surface of a target in which intermetallic compounds, oxides, carbides, carbonitrides and other substances without ductility exist in a highly ductile matrix phase, and thereby yield a significant effect of being able to prevent or inhibit the generation of particles during sputtering.

### EXAMPLES

The Examples of the present invention are now explained. These Examples are merely illustrative, and the present invention shall not in any way be limited by such Examples.

### Example 1

In Example 1, Co, Cr, Pt, and SiO₂ were used as the raw material, and a target raw material produced with the production process including powder mixing and sintering (powder metallurgy) was subject to primary processing of cutting using a lathe to achieve Ra of 0.30 μm and Rz of 1.50 μm. Subsequently, the material was subject to SSP (Sputtering Target Surface Polishing) including the steps of wet primary polishing based on pure water drop→wet secondary polishing based on alumina abrasive-grain drop in order to adjust the surface and obtain a target. An example of the micrograph of this target surface is shown in FIG. 5. As shown in FIG. 5, the existence of SiO₂ particles in a ductile Co-Cr-Pt alloy matrix can be acknowledged.

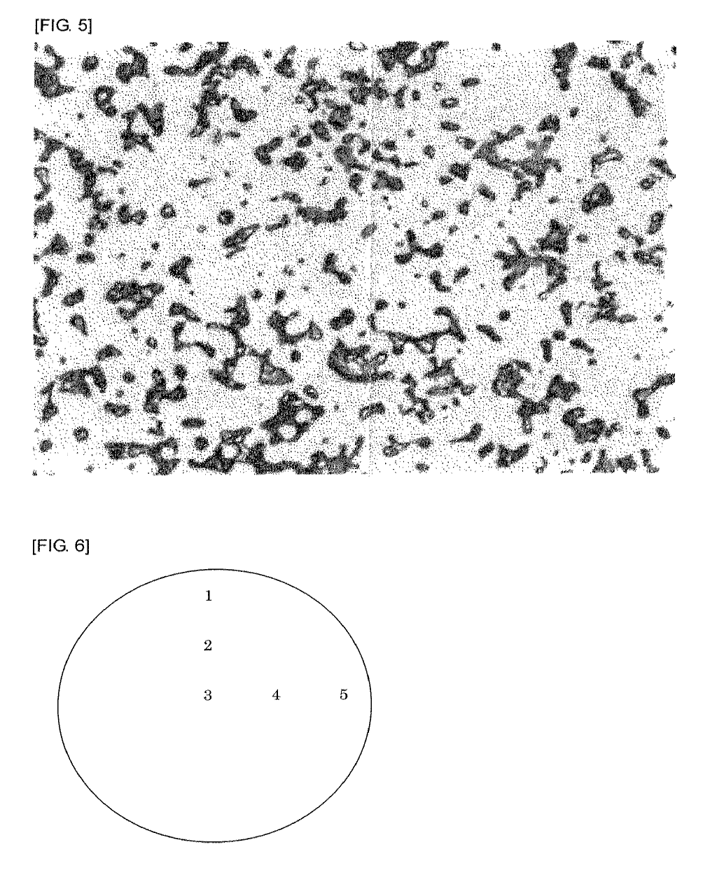

Next, the area ratio of defects and the ratio of (number of defects in a size of 0.001 to 0.04 μm²/total number of defects) were examined in this target. The results were respectively 0.486% and 86.69%. Note that the area ratio of defects and the number of defects were examined and obtained, as shown in FIG. 6, at five locations of the target surface having a diameter of 180 mm by selecting one arbitrary field of vision (100 μm×80 μm) and in accordance with the foregoing definition of defects of the target surface.

Subsequently, this target was used to form a sputtered film on a substrate in an Ar 1.5 Pa atmosphere under the DC sputtering condition of 30 w/cm².

When observing the particles that were generated during the sputtering, the size of the particles was approximately 0.8 to 18 μm (“average size”; hereinafter the same), and it was possible to reduce the occurrence of defectives caused by particles to 1.5%. The results are shown in Table 1.

TABLE 1

| | | | | Ratio (%) of | |
|---|---|---|---|---|---|
| | | Number of defects | | (Number of defects | Defect rate |
| | | in the size of 0.001 | Total number | in the size of 0.001 | caused by |
| | Area ratio of | to 0.04 μm² | of defects | to 0.04 μm²/Total | particles |
| | defects (%) | (quantity) | (quantity) | number of defects) | (%) |
| Example 1 | 0.486 | 469 | 541 | 86.69 | 1.5 |
| Example 2 | 0.237 | 431 | 462 | 93.29 | 1.2 |
| Comparative | 0.908 | 662 | 804 | 82.34 | 11.4 |
| Example 1 | | | | | |

### Example 2

In Example 2, Co, Cr, Pt, and SiO₂ were used as the raw material, and a target raw material produced with the production process including powder mixing and sintering (powder metallurgy) was subject to primary processing of cutting using a lathe to achieve Ra of 0.25 μm and Rz of 1.30 μm. Subsequently, the material was subject to SSP (Sputtering Target Surface Polishing) including the steps of wet primary polishing based on pure water drop→wet secondary polishing based on alumina abrasive-grain drop in order to adjust the surface and obtain a target.

Next, the area ratio of defects and the ratio of (number of defects in a size of 0.001 to 0.04 μm²/total number of defects) were examined in this target. The results were respectively 0.237% and 93.29%. Note that the area ratio of defects and the number of defects were examined and obtained as with Example 1.

Subsequently, this target was used to form a sputtered film on a substrate in an Ar 1.5 Pa atmosphere under the DC sputtering condition of 30 w/cm².

When observing the particles that were generated during the sputtering, the size of the particles was approximately 0.8 to 18 μm, and it was possible to reduce the occurrence of defectives caused by particles to 1.2%. The results are shown in Table 1.

### Comparative Example 1

In Comparative Example 1, as with Example 1, Co, Cr, Pt, and SiO₂ were used as the raw material, and a target material produced with the production process including powder mixing and sintering (powder metallurgy) was used, and subject to primary processing of cutting using a lathe. The cutting depth in the foregoing case was 0.5 mm. Subsequently, the material was subject to grinding processing in order to adjust the surface and obtain a target.

Next, the area ratio of defects and the ratio of (number of defects in a size of 0.001 to 0.04 μm²/total number of defects) were examined in this target. The results were respectively 0.908% and 82.34%. Note that the area ratio of defects and the number of defects were examined and obtained as with Example 1.

Subsequently, this target was used to form a sputtered film on a substrate in an Ar 1.5 Pa atmosphere under the DC sputtering condition of 30 w/cm².

When observing the particles generated during the sputtering, while the size of the particles was approximately 0.8 to 18 μm, the number of particles was extremely high; and the occurrence of defectives caused by particles increased to roughly 10%. The results are shown in Table 1.

As evident from comparing Examples 1 and 2 with Comparative Example 1, in the Examples the surface was formed with considerably small roughness but with smoothness. It was possible to reduce the number of nodules and the size of particles that were generated after sputtering the target and reduce the peeling of the particles which are especially problematic in forming a thin film, and reduce the level of defectiveness caused by the generation of particles.

Accordingly, it is evident that the surface finishing method including cutting work and grinding process of the present invention yields superior effects in the surface finishing of a target in which intermetallic compounds, oxides, carbides, carbonitrides and other substances without ductility exist in a highly ductile matrix phase at a volume ratio of 1 to 50%.

The present invention is able to obtain a target with superior surface characteristics in which the area ratio of defects on the target surface is 0.5% or less. As a result of sputtering this target, a superior effect is yielded in that the generation of particles and the generation of nodules after the use of the target can be significantly reduced. Accordingly, the present invention is particularly effective for a target in which intermetallic compounds, oxides, carbides, carbonitrides and other substances without ductility exist in a highly ductile matrix phase at a volume ratio of 1 to 50%.

1. A sintered sputtering target with reduced particle generation having a target surface in which intermetallic compounds, oxides, carbides, carbonitrides and other substances without ductility exist in a highly ductile matrix phase at a volume ratio of 1 to 50%, and in which the area ratio of defects including cracks and dents, caused by fallout of substances without ductility, and protrusions on the target surface is 0.5% or less.

2. The sintered sputtering target with reduced particle generation according to claim 1, wherein the number of defects in a size of 0.001 to 0.04 μm² on the target surface is 90% or more relative to the total number of defects.

3. A surface finishing method of a sintered sputtering target with reduced particle generation, wherein a target surface in which intermetallic compounds, oxides, carbides, carbonitrides and other substances without ductility exist in a highly ductile matrix phase at a volume ratio of 1 to 50% is preliminarily subject to primary processing of cutting work, then subsequently subject to finish processing via polishing in order to form a surface in which the area ratio of defects including cracks and dents, caused by fallout of substances without ductility, and protrusions on the target surface is 0.5% or less.

3. The surface finishing method of a sintered sputtering target according to claim 3, wherein the number of defects in a size of 0.001 to 0.04 μm² on the target surface is 90% or more relative to the total number of defects.
